(19) United States
(12) Patent Application Publication
(10) Pub. No.: US 2016/0039672 A1
(43) Pub. Date: Feb. 11, 2016

(54) OZONE GENERATOR AND METHOD OF DIAGNOSING FAILURE OF OZONE GENERATOR

(71) Applicant: NGK INSULATORS, LTD., Nagoya-City (JP)

(72) Inventors: Tatsuya TERAZAWA, Kasugai-City (JP); Shoji YOKOI, Nagoya-City (JP); Naoya TAKASE, Konan-City (JP)

(21) Appl. No.: 14/818,452

(22) Filed: Aug. 5, 2015

(30) Foreign Application Priority Data
Aug. 8, 2014 (JP) 2014-162065

(51) Int. Cl. C01B 13/11; G01R 31/02

(52) U.S. Cl. CPC C01B 13/115; G01R 31/027; C01B 2201/10

(57) ABSTRACT

An ozone generator includes a transformer, a direct current power supply unit connected to a primary side of the transformer, a reactor connected to a secondary side of the transformer, a semiconductor switch connected between one end of a primary winding of the transformer and the direct current power supply unit, and a control circuit for implementing ON-OFF control of the semiconductor switch to thereby apply alternating current voltage to the reactor. The control circuit implements control to minimize electric signal on the primary side of the transformer by updating a switching frequency by a fixed change width from a reference frequency, and determines that a failure has occurred if the number of updates by the fixed change width exceeds a threshold value.

### CROSS-REFERENCE TO RELATED APPLICATION

This application is based upon and claims the benefit of priority from Japanese Patent Application No. 2014-162065 filed on Aug. 8, 2014, the contents of which are incorporated herein by reference.

### BACKGROUND OF THE INVENTION

1. Field of the Invention

The present invention relates to an ozone generator and a method of diagnosing a failure of the ozone generator. More specifically, the present invention relates to an ozone generator and a method of diagnosing a failure of the ozone generator, e.g., suitable for in-vehicle applications.

2. Description of the Related Art

In general, in a discharge cell for ozone generation, it is widely known that when high voltage is applied by resonance operation, ozone is generated highly efficiently. In this case, it is suitable to utilize the resonance frequency of a resonance unit made up of the parasitic capacitance component of the discharge cell and an inductor connected in series with the discharge cell for driving an inverter at the resonance frequency to apply high voltage. A discharge cell discharging circuit described in Japanese Patent No. 5193086 is an example of an ozone generator for realizing this technique.

This discharge cell discharging circuit is a circuit made up of a pair of flat plates and a dielectric body for generating high concentration ozone. This discharge cell discharging circuit allows adjustment of the amount of ozone generation while automatically keeping the drive frequency of frequency applying means at a frequency near the resonance frequency at all times.

Specifically, the discharge cell discharging circuit has a tuning control unit for controlling the drive frequency of the inverter such that the resonance frequency of the resonance unit is tuned to the drive frequency of the inverter.

This tuning control unit implements feedback control of the inverter such that the drive frequency of the inverter is tuned to the resonance frequency of the resonance unit, based on the resonance phase difference signal indicating difference between the phase of the current flowing through the resonance unit on the secondary side of the transformer and the phase of the voltage of the resonance unit.

### SUMMARY OF THE INVENTION

The ozone generator is, e.g., mounted in a vehicle. In the ozone generator for use of in-vehicle applications, for example, ozone generated by the ozone generator is mixed into injected fuel in synchronization with the injection of fuel into a combustion chamber, to thereby facilitate ignition of the fuel.

According to the description of Japanese Patent No. 5193086, the tuning control unit of the discharge cell discharging circuit implements control by detecting the difference between the phase of the current flowing through the resonance unit on the secondary side of the transformer and the phase of the voltage of the resonance unit. If open circuit failures occur in discharge electrodes provided, e.g., in the reactor for generating ozone, it is required to detect the failure. However, in the conventional detection schemes based on detection of the current or the amount of generated ozone, the error tends to be large undesirably. In particular, in the case where the number of discharge electrodes is large, detection is difficult.

The present invention has been made taking such a problem into account, and an object of the present invention is to provide an ozone generator and a method of diagnosing a failure of the ozone generator, which make it possible to easily detect open circuit failures of discharge electrodes in a reactor, and easily determine whether or not operation of the ozone generator should be continued.

[1] An ozone generator according to a first aspect of the present invention includes a transformer, a direct current power supply unit connected to a primary side of the transformer, a reactor connected to a secondary side of the transformer, a switching unit connected between at least one end of a primary winding of the transformer and the direct current power supply unit, and a control circuit configured to implement ON-OFF control of the switching unit using a set switching frequency to thereby apply voltage to the reactor. The control circuit implements control to minimize electric signal on the primary side of the transformer by updating the switching frequency from a reference frequency by a fixed change width, and determines that a failure has occurred if a number of updates by the fixed change width exceeds a threshold value.

Firstly, by implementing the control to minimize the electric signal on the primary side of the transformer while updating the switching frequency from the reference frequency by the fixed change width, it becomes possible to tune the switching frequency to the resonance frequency on the secondary side. If open circuit failures occur in some of the electrode pairs, e.g., due to aged deterioration of the reactor, since the capacitance component corresponding to the electrode pairs having the open circuit failures is decreased, the resonance frequency on the secondary side is increased correspondingly. Consequently, the number of updates (number of update times of the switching frequency by the fixed change width) for implementing control to minimize the electric signal on the primary side of the transformer is increased. In view of this, the number of failed electrode pairs which may hinder, e.g., continuous operation of the ozone generator is determined beforehand as a preset number of the failed electrode pairs from experiment or simulation. Then, by using the number of updates corresponding to the preset number of the failed electrode pairs as a threshold value, it is possible to easily detect the open circuit failures of the discharge electrodes in the reactor, and easily determine whether or not operation of the ozone generator should be continued.

Further, the period during which the control is performed to minimize the electric signal on the primary side of the transformer while updating the switching frequency from the reference frequency in increments of the fixed change width can be not only a period from the start to the end of the first operation of the ozone generator (referred to as the first period for convenience), but also a period from the resumption of the ozone generator after the end of the first operation to the end of operation (referred to as the second period for convenience), in addition to the first period. The control period may include a plurality of the second periods. That is, the number of updates by the fixed change width is counted and accumulated only in the first period, or in a period including the first period and one or more second periods following the first period. Then, if the number of updates by the fixed change width, i.e., the accumulated number of updates exceeds the threshold value, it is determined that a failure has occurred.

[2] In the first aspect of the present invention, at the time of resumption of operation after the end of operation of the ozone generator, the control circuit may start the control from a frequency set at the end of the previous operation, instead of the reference frequency. The number of updates at the end of the previous operation may be used as an initial value, and counting of the number of updates may be resumed from the initial value.

This shows operation in the above-described period including the first period and one or more second periods following the first period. Each time operation is resumed in the second period, the above control is started from the frequency set at the end of the previous operation. That is, control is implemented to minimize the electric signal on the primary side of the transformer by updating the switching frequency, by the fixed change width, from the frequency set at the end of the previous operation. Then, in the second period, the number of updates at the end of the previous operation is used as an initial value, and counting of the number of updates is resumed from the initial value. That is, the number of updates required for shift of the frequency calculated based on the initial reference frequency and the frequency set at the end of the previous operation is used as an initial value, and counting of the number of updates is resumed from the initial value. Therefore, the number of updates by the fixed change width is accumulated in a period including the first period and one or more second periods following the first period. When the accumulated number of updates exceeds the threshold value, it is determined that a failure has occurred.

In this case, if the switching frequency is updated from the reference frequency by the fixed change width each time operation of the ozone generator is resumed, adjustment of the switching frequency becomes time consuming. However, at the time of resuming operation, since the above control can be started from the frequency set at the end of the previous operation, it is possible to achieve reduction in time required for adjustment of the switching frequency.

[3] In the first aspect of the present invention, the control circuit may increment the number of updates each time the switching frequency is updated by the fixed change width in one direction from the reference frequency, and may decrement the number of updates each time the switching frequency is updated by the fixed change width in a direction opposite to the one direction.

At the time of updating the switching frequency in increments of the fixed change width successively from the reference frequency, in the stage where the electric signal on the primary side of the transformer is minimized, mostly the process of updating the switching frequency by the fixed change width in one direction and the process of updating the switching frequency by the fixed change width in a direction opposite to the one direction are performed alternately. In such cases, if the number of updates is simply incremented one by one, even in the absence of the failed electrode pairs, the number of updates may exceed the threshold value undesirably. In view of this, by incrementing the number of updates each time the switching frequency is updated by the fixed change width in one direction from the reference frequency and by decrementing the number of updates each time the switching frequency is updated by the fixed change width in a direction opposite to the one direction, it is possible to easily and accurately detect open circuit failures of the discharge electrodes in the reactor, and it is possible to simply and reliably determine whether or not operation of the ozone generator should be continued.

[4] In the first aspect of the present invention, the reactor may include one or more electrode pairs each including two discharge electrodes spaced from each other by a predetermined gap length, and the reactor may generate ozone by allowing a source gas to pass through a space between at least the two discharge electrodes of the electrode pair and then causing electric discharge between the two discharge electrodes by the voltage applied between the two discharge electrodes.
[5] In this case, among the electrode pairs, as the number of electrode pairs having an open circuit failure increases, the number of updates may increase.
[6] Further, the threshold value may be the number of updates corresponding to a specific number of electrode pairs having an open circuit failure.
[7] In the first aspect of the present invention, the switching unit may be connected between the one end of the primary winding of the transformer and the direct current power supply unit.
[8] In this case, the control circuit may implement control to minimize the current value on the primary side of the transformer by updating the switching frequency from the reference frequency by the fixed change width.

In this manner, since it is sufficient to only detect the current value on the primary side, the circuit structure of the ozone generation is simple, and it becomes possible to easily tune the switching frequency for turning on and off the switching unit to the resonance frequency on the secondary side of the transformer.

[9] Alternatively, the control circuit may implement control to minimize the power value on the primary side of the transformer by updating the switching frequency from the reference frequency by the fixed change width.

In this control, by referring to the power value obtained from the voltage value and the current value on the primary side, even in the case where the power supply voltage of the direct current power supply unit varies, it is possible to easily tune the switching frequency for turning on and off the switching unit to the resonance frequency on the secondary side of the transformer.

[10] In the first aspect of the present invention, the switching unit may be connected between both ends of the transformer and both ends of the direct current power supply unit.
[11] In this case, the control circuit may implement control to cause the phase difference between current and voltage on the primary side of the transformer to become zero by updating the switching frequency from the reference frequency by the fixed change width.

In this control, since the phase difference between the current and the voltage on the primary side of the transformer is referred to, the ozone generator can be suitably used as an ozone generator having an inverter connected between the transformer and the direct current power supply unit. It is possible to easily tune the switching frequency for turning on and off the inverter to the resonance frequency on the secondary side of the transformer.

[12] In a method of diagnosing a failure of an ozone generator according to a second aspect of the present invention, the ozone generator includes a transformer, a direct current power supply unit connected to a primary side of the transformer, a reactor connected to a secondary side of the transformer, a switching unit connected between at least one end of a primary winding of the transformer and the direct current power supply unit, and a control circuit configured to implement ON-OFF control of the switching unit by a set switching frequency to thereby apply voltage to the reactor. The method includes a control step of implementing control to minimize electric signal on the primary side of the transformer by updating the switching frequency from a reference frequency by a fixed change width, and a determination step of determining that a failure has occurred if the number of updates by the fixed change width exceeds a threshold value.
[13] In the second aspect of the present invention, at the time of resumption of operation of the ozone generator after the end of operation of the ozone generator, the control may be started from a frequency set at the end of previous operation, instead of the reference frequency, and the number of updates at the end of the previous operation may be used as an initial value, and counting of the number of updates may be resumed from the initial value.
[14] In the second aspect of the present invention, in the control step, the number of updates may be incremented each time the switching frequency is updated by the fixed change width in one direction from the reference frequency, and the number of updates may be decremented each time the switching frequency is updated by the fixed change width in a direction opposite to the one direction.

In the ozone generator and the method of diagnosing a failure of the ozone generator according to the present invention, it is possible to easily detect open circuit failures of the discharge electrodes in the reactor, and easily determine whether or not operation of the ozone generator should be continued.

The above and other objects, features and advantages of the present invention will become more apparent from the following description when taken in conjunction with the accompanying drawings in which preferred embodiments of the present invention are shown by way of illustrative example.

### BRIEF DESCRIPTION OF THE DRAWINGS

FIG. 1 is a circuit diagram showing structure of an ozone generator (first ozone generator) according to a first embodiment;

FIG. 2 is a vertical cross sectional view enlargedly showing main components of a reactor;

FIG. 3 is a cross sectional view taken along a line III-III in FIG. 2;

FIG. 4 is a timing chart showing operation of the first ozone generator;

FIG. 5 is a graph showing change of current value on the primary side with respect to the switching frequency in the first ozone generator;

FIG. 6A is a diagram showing a case where failure determination is made in a period (first period) from the start to the end of the first operation of the ozone generator;

FIG. 6B is a diagram showing a case where failure determination is made in a period (second period) from the resumption to the end of operation after the first period;

FIG. 7 is a flow chart (No. 1) showing operation of the first ozone generator;

FIG. 8 is a flow chart (No. 2) showing operation of the first ozone generator;

FIG. 9 is a circuit diagram showing structure of an ozone generator (second ozone generator) according to a second embodiment;

FIG. 10 is a graph showing change of power value on the primary side with respect to the switching frequency, in the second ozone generator;

FIG. 11 is a flow chart (No. 1) showing operation of the second ozone generator;

FIG. 12 is a flow chart (No. 2) showing operation of the second ozone generator;

FIG. 13 is a circuit diagram showing structure of an ozone generator (third ozone generator) according to a third embodiment;

FIG. 14 is a graph showing change in the phase difference between the voltage and current on the primary side with respect to the switching frequency, in the third ozone generator; and

FIG. 15 is a flow chart showing operation of the third ozone generator.

### DESCRIPTION OF THE PREFERRED EMBODIMENTS

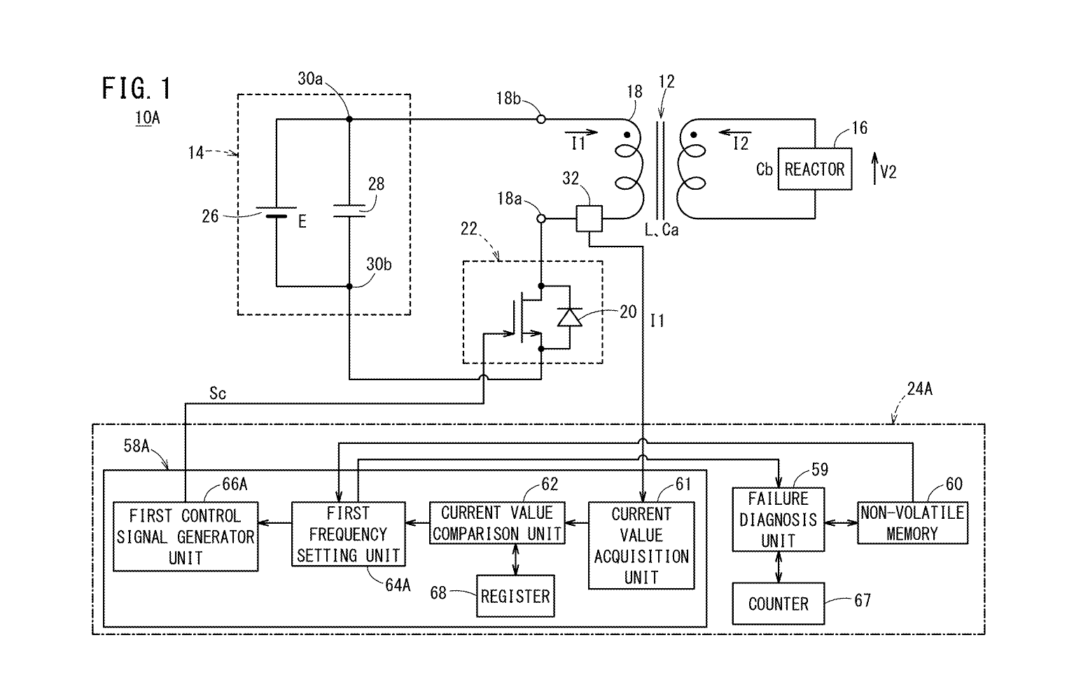

Hereinafter, preferred embodiments of ozone generators according to the present invention will be described with reference to FIGS. 1 to 15.

Firstly, as shown in FIG. 1, an ozone generator according to a first embodiment of the present invention (hereinafter referred to as a first ozone generator 10A) includes a transformer 12, a direct current power supply unit 14 connected to the primary side of the transformer 12, a reactor 16 connected to the secondary side of the transformer 12, a semiconductor switch (switching unit) 22 connected between one end 18a of a primary winding 18 of the transformer 12 and the direct current power supply unit 14, and having a diode 20 connected in reverse-parallel, and a first control circuit 24A for applying voltage to the reactor 16 by implementing ON-OFF control of the semiconductor switch 22.

The direct current power supply unit 14 is formed by connecting a direct current power supply 26 and a capacitor 28 in parallel. Therefore, a positive electrode terminal 30a of the direct current power supply unit 14 (node between a positive (+) terminal of the direct current power supply 26 and one electrode of the capacitor 28) and the other end 18b of the primary winding 18 are connected, and the semiconductor switch 22 is connected between a negative electrode terminal 30b of the direct current power supply unit 14 (node between a negative (−) terminal of the direct current power supply 26 and the other electrode of the capacitor 28) and the one end 18a of the primary winding 18. In the example of FIG. 1, the semiconductor switch 22 is provided on the part of the negative electrode terminal 30b of the direct current power supply unit 14. However, it is a matter of course that the same advantages can be obtained also in the case where the semiconductor switch 22 is provided on the part of the positive electrode terminal 30a.

As the semiconductor switch 22, a self-extinguishing device or a commutation extinguishing device may be used. In this embodiment, the semiconductor switch 22 uses a field effect transistor, e.g., a metal oxide semiconductor field effect transistor (MOSFET) having an internal diode 20 connected in reverse-parallel. The MOSFET may be a SiC-MOSFET using SiC (Silicon Carbide).

The first control circuit 24A generates a switching control signal (hereinafter referred to as the control signal Sc) for implementing ON-OFF control of the semiconductor switch 22. The control signal Sc from the first control circuit 24A is applied to the gate of the semiconductor switch 22. By the first control circuit 24A, ON-OFF control of the semiconductor switch 22 is implemented.

The first ozone generator 10A has current detection means 32 for detecting the current (current value I1) flowing through the primary side of the transformer 12. Although any means capable of detecting the current (current value I1) flowing through the primary side of the transformer 12 can be used as the current detection means 32, preferably, a non-contact type direct current meter, e.g., comprising DCCT (direct current transformer) should be adopted.

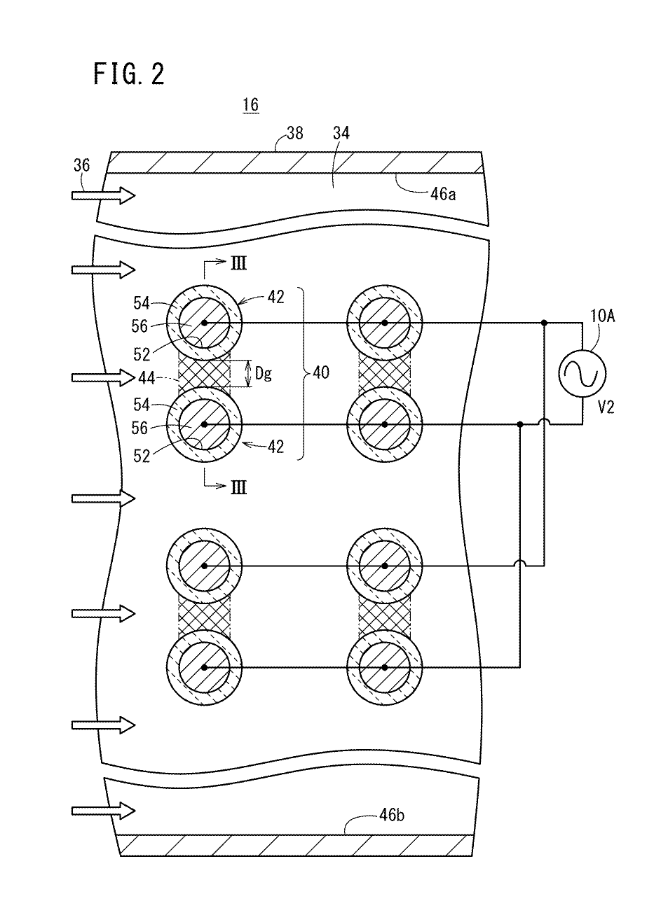

As shown in FIG. 2, the reactor 16 includes a casing 38 having a hollow portion 34 and at least one electrode pair 40 placed in the hollow portion 34 of the casing 38. A source gas 36 is supplied to the hollow portion 34. The electrode pair 40 comprises two discharge electrodes 42 spaced from each other by a predetermined gap length Dg.

The reactor 16 generates ozone by allowing the source gas 36 to pass through a space between at least two discharge electrodes 42 of the electrode pair 40 to thereby cause electric discharge between the two discharge electrodes 42. The space between two discharge electrodes 42 is a space where electric discharge occurs, and thus the space is defined as a discharge space 44.

In particular, in the embodiment of the present invention, a plurality of electrode pairs 40 are arranged in series or in parallel, or arranged in series and in parallel, between inner walls (one inner wall 46a and the other inner wall 46b) of the casing 38 that face each other. In the example of FIG. 2, the electrode pairs are arranged in series and in parallel.

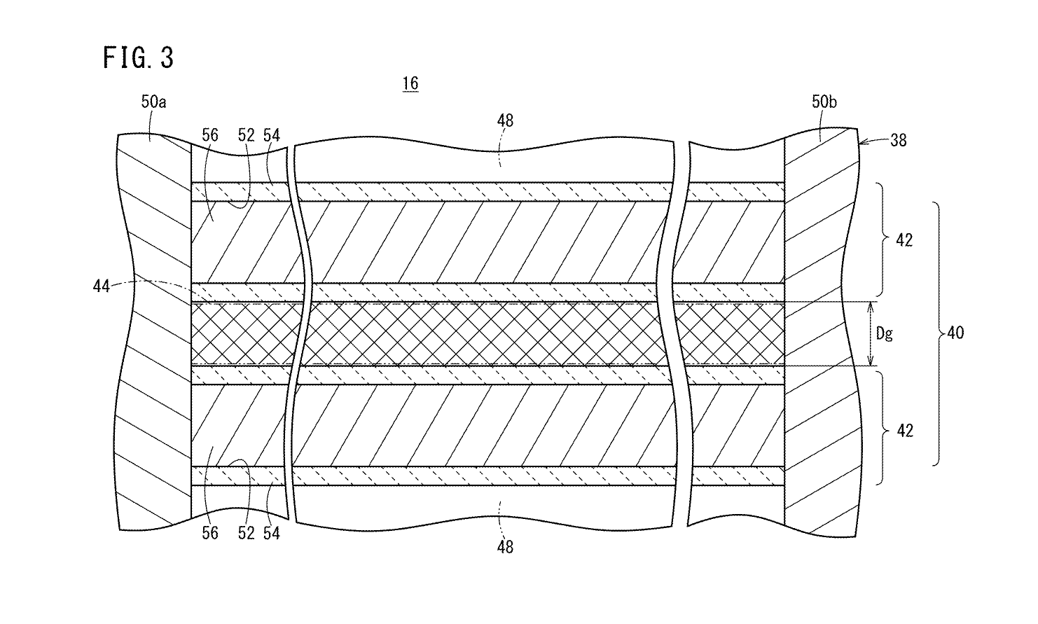

As shown in FIG. 3, each of the discharge electrodes 42 has a rod shape, and extends along a source gas passing surface 48 having the normal direction in the main flow direction of the source gas 36. Each of the discharge electrodes 42 extends between one side wall 50a and the other side wall 50b of the casing 38. That is, the discharge electrodes 42 extend across the hollow portion 34 of the casing 38 along the source gas passing surface 48, and are fixed to the one side wall 50a and the other side wall 50b of the casing 38. The main flow direction of the source gas 36 herein means a flow direction of the source gas 36 flowing at the central portion with directivity. This is intended to exclude directions of flow components without directivity in the marginal portions of the source gas 36.

Each of the discharge electrodes 42 includes a tubular dielectric body 54 having a hollow portion 52 and a conductor 56 positioned inside the hollow portion 52 of the dielectric body 54. In the example of FIGS. 2 and 3, the dielectric body 54 has a cylindrical shape, and the hollow portion 52 has a circular shape in transverse cross section. The conductor 56 has a circular shape in transverse cross section. It is a matter of course that the shapes of the dielectric body 54 and the conductor 56 are not limited to these shapes. The dielectric body 54 may have a polygonal cylindrical shape such as a triangle, quadrangle, pentagonal, hexagonal, or octagonal shape in transverse cross section. Correspondingly, the conductor 56 may have a polygonal columnar shape such as a triangle, quadrangle, pentagonal, hexagonal, or octagonal shape in transverse cross section.

The present embodiment is aimed at generation of ozone. Therefore, the source gas 36 may be a gas containing, for example, atmospheric air or oxygen. In this case, the gas may be air which has not been dehumidified.

Preferably, the conductor 56 is made of a material selected from a group consisting of molybdenum, tungsten, stainless steel, silver, copper, nickel, and alloy at least including one of these materials. As the alloy, for example, invar, kovar, Inconel (registered trademark), or Incoloy (registered trademark) may be used.

Further, preferably, the dielectric body 54 may be made of a ceramics material which can be fired at a temperature less than the melting point of the conductor 56. More specifically, the dielectric body 54 should preferably be made of single or complex oxide or complex nitride containing at least one material selected from a group consisting of, for example, barium oxide, bismuth oxide, titanium oxide, zinc oxide, neodymium oxide, titanium nitride, aluminum nitride, silicon nitride, alumina, silica, and mullite.

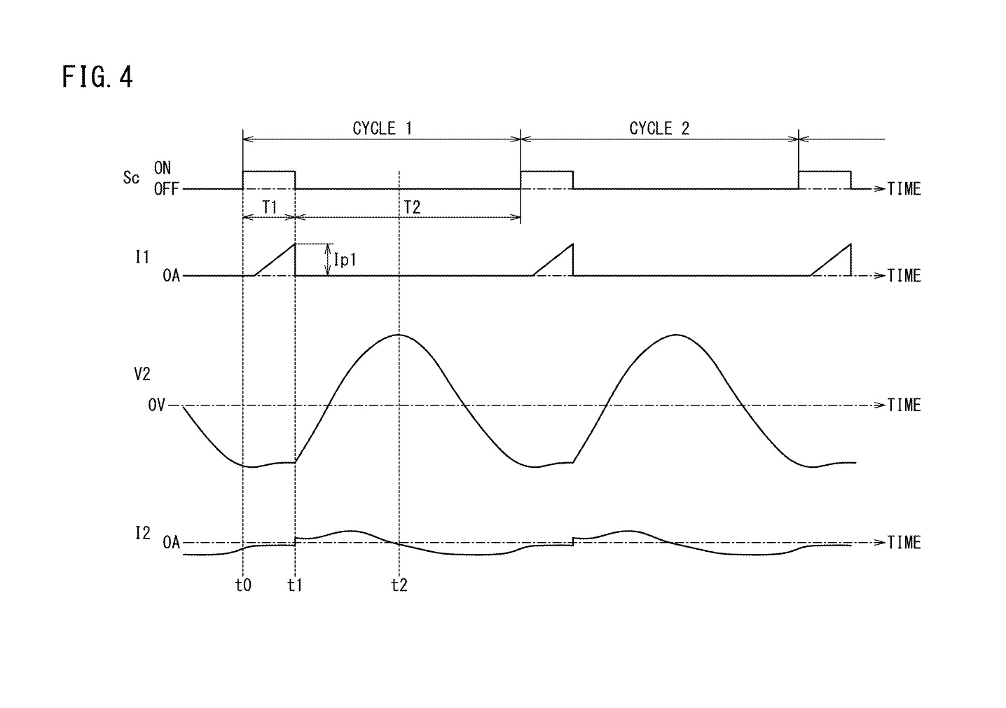

Next, operation of the first ozone generator 10A will be described with reference to FIG. 4.

Firstly, at the start point t0 of the cycle 1, when the semiconductor switch 22 is turned on. e.g., based on the input of the control signal Sc, voltage substantially equal to the power supply voltage E of the direct current power supply unit 14 is applied to the transformer 12 over the ON period T1 of the semiconductor switch 22. The primary current I1 flowing through the primary winding 18 of the transformer 12 increases linearly over time with a slope (E/L) where L denotes the primary inductance (excitation inductance) of the transformer 12. Induction energy is then accumulated in the transformer 12.

Thereafter, at the time point t1 where the primary current I1 reaches a predetermined peak value Ip1, when the semiconductor switch 22 is turned off, supply of alternating current high voltage V2 (secondary voltage) to the reactor 16 is started and the secondary current I2 flows in the positive direction. Then, at the time point t2 where the alternating current voltage V2 has a peak value, the secondary current I2 becomes zero. After the time point t2, the secondary current I2 flows in the negative direction.

The cycle 2 is started after the OFF period T2 of the semiconductor switch 22, and operation in the same manner as the above cycle 1 is repeated. Consequently, alternating current high voltage V2 is applied to the reactor 16.

Then, the first ozone generator 10A tunes the switching frequency f for turning on and off the semiconductor switch 22 to the secondary resonance frequency fc made up of the excitation inductance L and the winding capacitance Ca of the transformer 12, and the capacitance Cb between the discharge electrodes 42 of the reactor 16 to thereby achieve improvement in the efficiency of ozone generation.

In this regard, the first control circuit 24A controls the frequency of the alternating current voltage V2 applied to the reactor 16 such that the electrical signal on the primary side of the transformer 12 is minimized. In particular, in this first ozone generator 10A, the frequency of the alternating current voltage V2 applied to the reactor 16 is controlled such that the direct-current (DC) component of the current value I1 on the primary side of the transformer 12 is minimized.

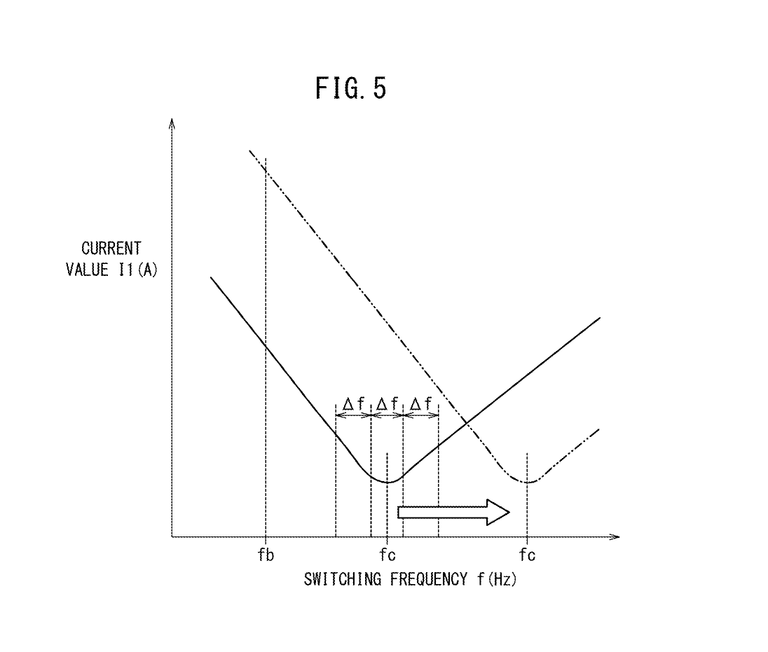

Specifically, as shown in FIG. 5, by successively changing the switching frequency f from a preset reference frequency fb in one direction (toward the higher frequency) in increments of a fixed change width Δf, the current value I1 (direct current component) on the primary side of the transformer 12 is decreased gradually. However, after the switching frequency f exceeds a certain frequency, the current value I1 is increased gradually. By setting the frequency f to a frequency corresponding to the minimum value of this current value I1, it becomes possible to tune the switching frequency f to the resonance frequency fc on the secondary side. It should be noted that, preferably, the reference frequency fb is lower than the resonance frequency fc as shown in FIG. 5.

Further, in some cases, open circuit failures may occur in some of the plurality of electrode pairs 40, e.g., due to aged deterioration of the reactor 16, and the electrode pairs 40 having the open circuit failures may not contribute to ozone generation. If the number of electrode pairs 40 having the open circuit failures (hereinafter referred to as the failed electrode pairs 40) is large, the entire capacitance Cb between the discharge electrodes 42 is decreased. For example, in FIG. 5, as shown by a two dot chain line, the resonance frequency fc on the secondary side is increased. Correspondingly, the number of update times (the number of updates) of the switching frequency f by the fixed change width Δf from the reference frequency fb is increased as well. In other words, the number of times the switching frequency f is increased by the fixed change width Δf needs to be increased accordingly. Further, if the number of failed electrode pairs 40 is increased, the number of electrode pairs 40 that do not contribute to ozone generation is increased. For this reason, ozone generation efficiency is lowered.

Therefore, in the embodiment of the present invention, for example, the number of failed electrode pairs 40 which may hinder continuous operation of the first ozone generator 10A is determined beforehand by experiments or simulations as a preset number. It is a matter of course that the ratio of the number of failed electrode pairs 40 to the total number of the electrode pairs 40 provided in the reactor 16 may be determined as a preset ratio. Further, the number of updates N by the fixed change width Δf corresponding to the preset number or ratio of the failed electrode pairs 40 is determined, e.g., by experiments or simulations, and this number of updates N is used as a threshold value Nth.

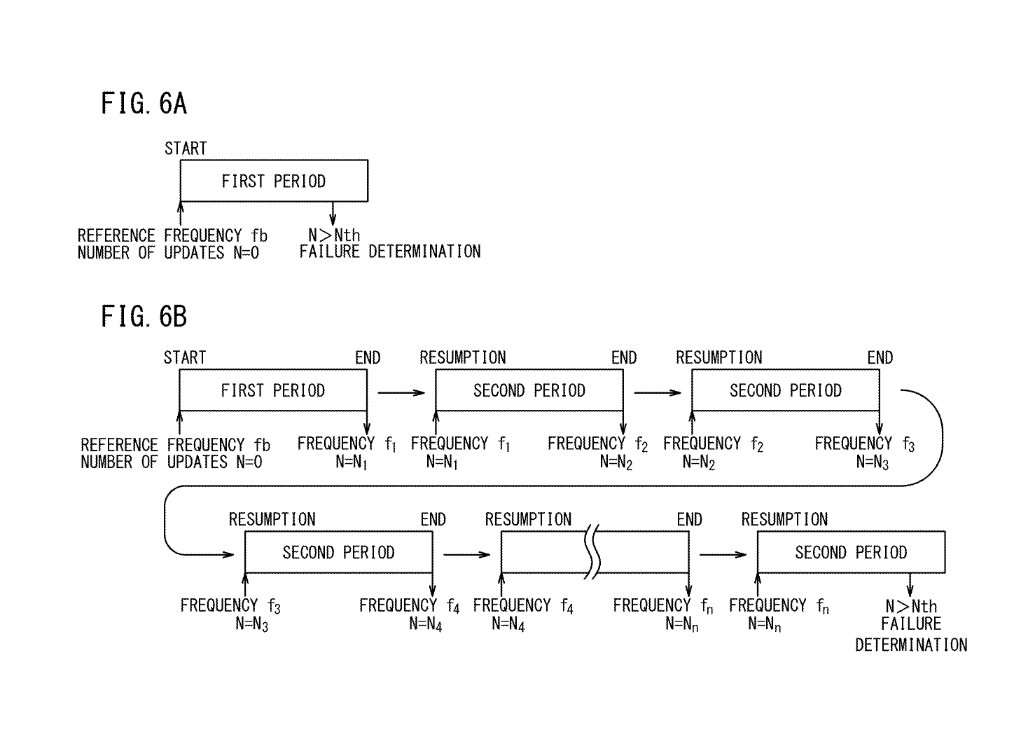

Further, a control period where control is implemented to minimize the current value I1 of the transformer 12 on the primary side while updating the switching frequency f from the reference frequency fb by the fixed change width Δf (i.e., in increments of the fixed change width Δf) can be a period from the start to the end of the first operation of the first ozone generator 10A (referred to as “a first period” for convenience) as shown in FIG. 6A, and also can be, in addition to the first period, a period from the resumption after the end of operation of the first ozone generator 10A, to the end of operation of the first ozone generator 10A, (referred to as “a second period” for convenience) as shown in FIG. 6B. The control period may include a plurality of the second periods. That is, the number of updates N of the fixed change width Δf is counted and accumulated only in the first period, or in a period including the first period and one or more second periods following the first period. Then, when the number of updates N of the fixed change width Δf, i.e., the accumulated number of updates N exceeds the threshold value Nth, it is determined that a failure has occurred.

As shown in FIG. 6B, in each second period, at the time of the resumption of operation, control is started from the frequency at the end of the previous operation. That is, the control is implemented to minimize the current value I1 on the primary side of the transformer 12 by updating the switching frequency f, by the fixed change width Δf, from the frequency at the end of the previous operation. Then, in the second period, the number of updates at the end of the previous operation is used as an initial value, and counting of the number of updates N is resumed from the initial value. That is, the number of updates N required for movement of the frequency calculated based on the initial reference frequency fb and the frequency at the end of the previous operation is used as an initial value, and counting of the number of updates N is resumed from the initial value. Therefore, the number of updates N of the fixed change width Δf is accumulated in a period including the first period and the following one or more second periods. When the accumulated number of updates N exceeds the threshold value Nth, it is determined that a failure has occurred.

Next, structure and operation of the first control circuit 24A of the first ozone generator 10A will be described with reference to FIGS. 1, 4, 5, 7, and 8.

Firstly, as shown in FIG. 1, the first control circuit 24A includes a first switching control unit 58A, a failure diagnosis unit 59, and a non-volatile memory 60.

The first switching control unit 58A implements control to minimize the electrical signal on the primary side of the transformer 12 by updating the switching frequency f from the reference frequency fb by the fixed change width Δf. Specifically, the first switching control unit 58A includes a current value acquisition unit 61 for acquiring the current value I1 from current detection means 32, a current value comparison unit 62 for comparing the previously acquired current value I1 with the presently acquired current value I1, a first frequency setting unit 64A for setting the switching frequency f to turn on and off the semiconductor switch 22 in correspondence with transition of the current value I1, and a first control signal generator unit 66A for generating and outputting a control signal Sc in correspondence with the set switching frequency f.

When the number of updates N by the fixed change width Δf exceeds the threshold value Nth, the failure diagnosis unit 59 determines that a failure has occurred. In this case, each time the switching frequency f is updated by the fixed change width Δf in one direction from the reference frequency fb, the number of updates N is incremented, and each time the switching frequency f is updated by the fixed change width Δf in a direction opposite to the one direction from the reference frequency fb, the number of updates N is decremented. The number of updates N is incremented and decremented using a counter 67.

Further, at the end of operation of the first ozone generator 10A, the failure diagnosis unit 59 reads the number of updates N held in the counter 67, and stores the read number of updates N in the non-volatile memory 60. At the time of resumption of operation of the first ozone generator 10A, the failure diagnosis unit 59 reads, from the non-volatile memory 60, the number of updates N read at the time of the end of previous operation, and stores the read number of updates N as an initial value in the counter 67.

At the time of starting operation (starting operation herein does not mean resumption of operation; the same applies hereinafter), the first frequency setting unit 64A of the first switching control unit 58A sets the switching frequency f to the reference frequency fb. Further, at the time of resumption of operation, the first frequency setting unit 64A sets the switching frequency f to the frequency at the end of the previous operation. The frequency at the end of the previous operation can be obtained by multiplying the number of updates at the end of the previous operation (number of updates stored in the non-volatile memory 60) by the fixed change width Δf, and adding the resulting value to the reference frequency fb.

It should be noted that, at the time of starting operation, zero is stored as an initial value in the non-volatile memory 60 and the counter 67.

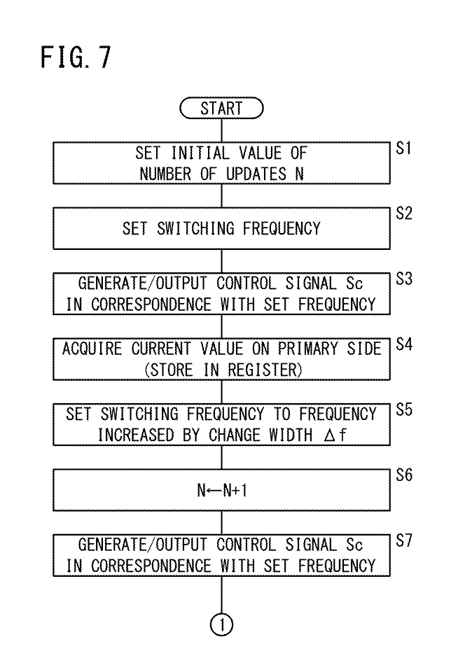

Then, in step S1 of FIG. 7, the failure diagnosis unit 59 sets the initial value of the number of updates N by the fixed change width Δf. The number of updates N is read from the non-volatile memory 60, and the read number of updates N is stored as the initial value in the counter 67. At the time of starting operation, since zero is stored in the non-volatile memory 60, the counter 67 stores therein zero as an initial value.

In step S2, the first frequency setting unit 64A sets the switching frequency f. Specifically, the number of updates N stored in the non-volatile memory 60 is multiplied by the fixed change width Δf, and the resulting value is added to the reference frequency fb to thereby obtain a frequency. Then, the obtained frequency is set as the switching frequency f. At the time of starting operation, since zero is stored in the non-volatile memory 60, the switching frequency f is the reference frequency fb.

In step S3, the first control signal generator unit 66A generates and outputs the control signal Sc in correspondence with the set switching frequency f.

In step S4, the current value acquisition unit 61 acquires the current value I1 from the current detection means 32, and stores the current value I1 in a register 68.

In step S5, the first frequency setting unit 64A sets the switching frequency to a frequency which is higher than the current frequency by a preset fixed change width Δf.

Thereafter, in step S6, the failure diagnosis unit 59 increments the value (number of updates N) of the counter 67 by 1.

In step S7, the first control signal generator unit 66A generates and outputs the control signal Sc in correspondence with the set frequency.

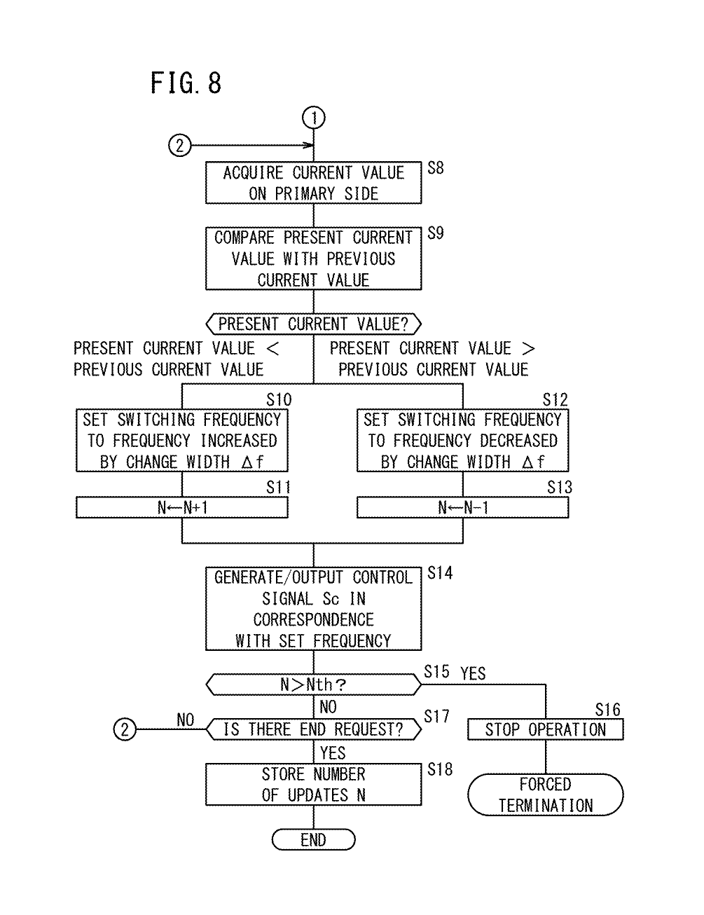

In step S8 of FIG. 8, the current value acquisition unit 61 acquires the current value I1 from the current detection means 32.

In step S9, the current value comparison unit 62 compares the acquired current value I1 (present current value) with the previous current value I1 stored in the register 68.

In the case where the present current value I1 is lower than the previous current value I1, the routine proceeds to step S10, and the first frequency setting unit 64A sets the switching frequency f to a frequency which is higher than the present frequency by the preset fixed change width Δf.

Thereafter, in step S11, the failure diagnosis unit 59 increments the value (number of updates N) of the counter 67 by 1.

If the present current value I1 is higher than the previous current value I1, the routine proceeds to step S12, and the first frequency setting unit 64A sets the switching frequency f to a frequency which is lower than the present frequency by the preset fixed change width Δf.

Thereafter, in step S13, the failure diagnosis unit 59 decrements the value (number of updates N) of the counter 67 by 1.

When the process in step S11 or the process in step S13 is finished, the routine proceeds to the next step S14, and the first control signal generator unit 66A generates and outputs the control signal Sc in correspondence with the set switching frequency f.

In the next step S15, the failure diagnosis unit 59 determines whether the value (number of updates N) of the counter 67 exceeds the threshold value Nth. If the value of the counter 67 exceeds the threshold value Nth, the routine proceeds to step S16, and it is determined that continuous operation of the first ozone generator 10A is hindered. Therefore, operation of the first ozone generator 10A is stopped, and the process of the first ozone generator 10A is forcibly terminated. An alarm may be issued additionally.

In the above step S15, if it is determined that the value (number of updates N) of the counter 67 is equal to or less than the threshold value Nth, the routine proceeds to the next step S17, and it is determined whether or not there is a request for stopping operation of the first ozone generator 10A. If there is no request for stopping operation, the routine returns to step S8 to repeat the processes of step S8 and the subsequent steps.

In step S17, if there is a request for stopping operation, the routine proceeds to step S18, and the failure diagnosis unit 59 stores the present number of updates N in the non-volatile memory 60. Thereafter, operation of the first ozone generator 10A is finished.

Next, when operation is resumed, in step S1 of FIG. 7, the failure diagnosis unit 59 reads the number of updates N from the non-volatile memory 60, and stores the read number of updates N as an initial value in the counter 67. That is, the number of updates N at the end of the previous operation is stored as an initial value in the counter 67. In the subsequent step S2, the number of updates N at the end of the previous operation is multiplied by the fixed change width Δf, and the resulting value is added to the reference frequency fb to thereby obtain a frequency. The obtained frequency is set as the switching frequency f. Then, the processes of step S3 and the subsequent steps are repeated.

As described above, the first ozone generator 10A controls the frequency of the alternating current voltage V2 applied to the reactor 16 such that the current value I1 on the primary side of the transformer 12 is minimized. Thus, it is possible to easily tune the switching frequency f for turning on and off the semiconductor switch 22 to the resonance frequency fc on the secondary side of the transformer 12. Therefore, improvement in the efficiency of ozone generation can be easily realized, and the high efficiency in ozone generation can be maintained all the time. Further, since it is not required for the first control circuit 24A to refer to the high voltage, etc. on the secondary side, the circuit structure is simple, and size reduction can be achieved. Further, since it is sufficient to only detect the current value I1 on the primary side, the circuit structure of the first ozone generator 10A is simple, and it becomes possible to easily tune the switching frequency f for turning on and off the semiconductor switch 22 to the resonance frequency fc on the secondary side of the transformer 12.

Accordingly, for example, the first ozone generator 10A can be suitably used for the ozone generator mounted in a vehicle. In an application of the in-vehicle ozone generator, for example, ozone generated by the ozone generator is mixed into injection fuel in accordance with the timing of fuel injection into a combustion chamber to thereby facilitate ignition of the fuel.

Further, in the first ozone generator 10A, the number of failed electrode pairs 40 which may affect continuous operation of the first ozone generator 10A is determined beforehand as a preset number, and the number of updates N corresponding to the preset number of failed electrode pairs 40 is used as the threshold value Nth. Therefore, as described above, in the process of implementing control to minimize the current value I1 on the primary side of the transformer 12 while updating the switching frequency f from the reference frequency fb by the fixed change width Δf, it is possible to easily detect open circuit failures of the electrode pairs 40 in the reactor 16, and simply determine whether or not operation of the first ozone generator 10A should be continued.

In a case of updating the switching frequency f by the fixed change width Δf successively from the reference frequency fb, in the stage where the current value I1 on the primary side of the transformer 12 is minimized, mostly, the process of updating the switching frequency f by the fixed change width Δf in one direction and the process of updating the switching frequency f by the fixed change width Δf in a direction opposite to the one direction are performed alternately. In such cases, if the number of updates N is incremented one by one, even in the absence of the failed electrode pairs 40, the number of updates N may exceed the threshold value Nth undesirably.

In view of this, each time the switching frequency f is updated by the fixed change width Δf in one direction from the reference frequency fb, the number of updates N is incremented, and each time the switching frequency f is updated by the fixed change width Δf in a direction opposite to the one direction from the reference frequency fb, the number of updates N is decremented. Owing thereto, it is possible to easily and accurately detect open circuit failures of the electrode pairs 40 in the reactor 16, and it is possible simply and reliably determine whether or not operation of the first ozone generator 10A should be continued.

Further, in the first ozone generator 10A, at the time of resumption of operation after the end of operation of the first ozone generator 10A, the above control is started from the frequency at the end of the previous operation, not from the reference frequency fb. The number of updates at the end of the previous operation is used as an initial value, and counting of the number of updates N is resumed from the initial value. If updating of the switching frequency f is started from the reference frequency fb in increments of the fixed change width Δf each time operation of the first ozone generator 10A is resumed, adjustment of the switching frequency f becomes time consuming. However, at the time of resuming operation, since the above control can be started from the frequency set at the end of the previous operation, it is possible to achieve reduction in time required for adjustment of the switching frequency f.

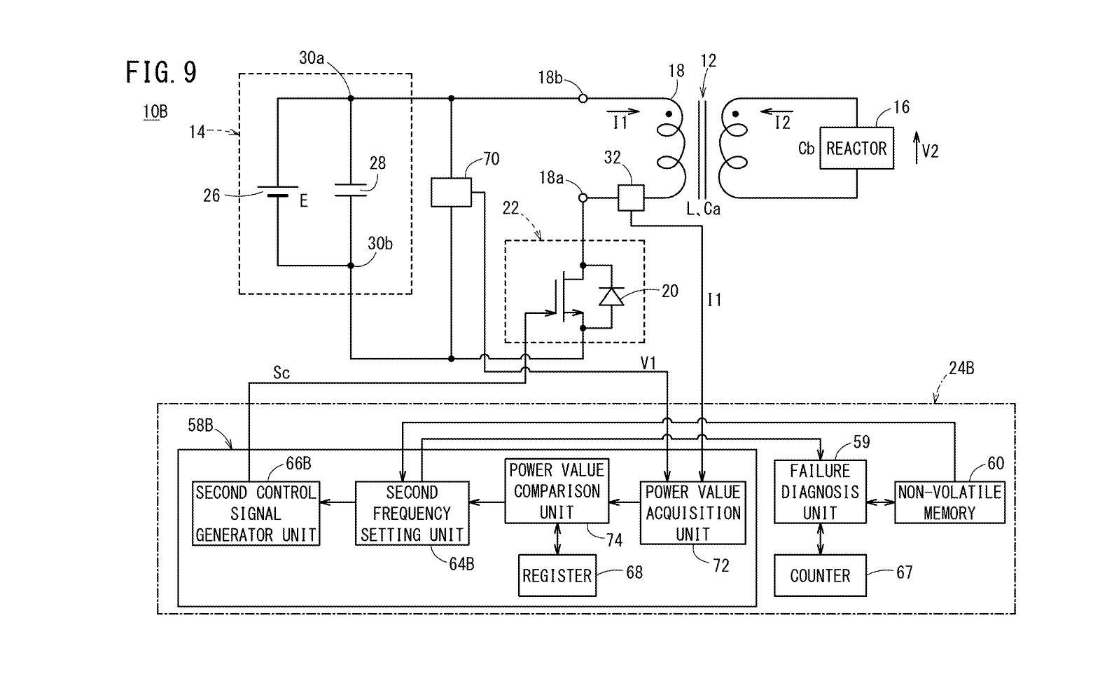

Next, an ozone generator according to a second embodiment of the present invention (hereinafter referred to as a second ozone generator 10B) will be described with reference to FIGS. 9 to 12.

As shown in FIG. 9, the second ozone generator 10B has substantially the same structure as the above described first ozone generator 10A. However, the second ozone generator 10B is different from the first ozone generator 10A in that the second ozone generator 10B has a control circuit (second control circuit 24B) which controls the frequency of the alternating current voltage V2 applied to the reactor 16 such that the power value P1 on the primary side of the transformer 12 is minimized.

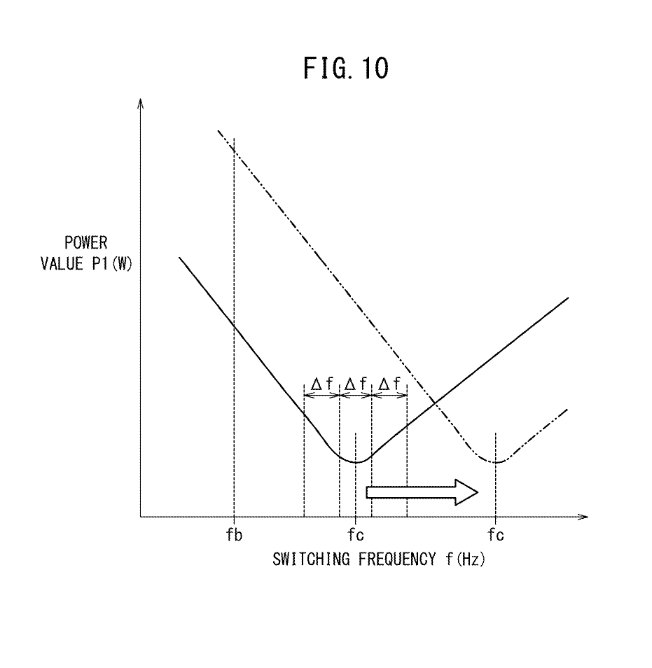

As shown in FIG. 10, by successively changing the switching frequency f by the fixed change width Δf in one direction from the preset reference frequency fb, the power value P1 on the primary side of the transformer 12 is decreased gradually. However, when the switching frequency f exceeds a certain frequency, the power value P1 on the primary side of the transformer 12 is increased gradually. By setting the switching frequency f to a frequency corresponding to the minimum value of this power value P1, it becomes possible to tune the switching frequency f to the resonance frequency fc on the secondary side.

Further, also in this second ozone generator 10B, if the number of failed electrode pairs 40 is increased due to aged deterioration or the like of the reactor 16, as shown by a two dot chain line in FIG. 10, the resonance frequency fc on the secondary side is increased. Correspondingly, the number of update times (number of updates N) of the switching frequency f by the fixed change width Δf from the reference frequency fb is increased as well.

In view of the above, as shown in FIG. 9, the second ozone generator 10B includes voltage detection means 70 for detecting the direct current voltage (voltage value V1) on the primary side, a second switching control unit 58B, a failure diagnosis unit 59, and a non-volatile memory 60.

The second switching control unit 58B includes a power value acquisition unit 72 for multiplying the voltage value V1 from the voltage detection means 70 by the current value I1 from the current detection means 32 to thereby determine the power value P1, a power value comparison unit 74 for comparing the previously acquired power value with the presently acquired power value, a second frequency setting unit 64B for setting the switching frequency f for turning on and off the semiconductor switch 22 in correspondence with transition of the power value P1, and a second control signal generator unit 66B for generating and outputting the control signal Sc in correspondence with the set switching frequency f.

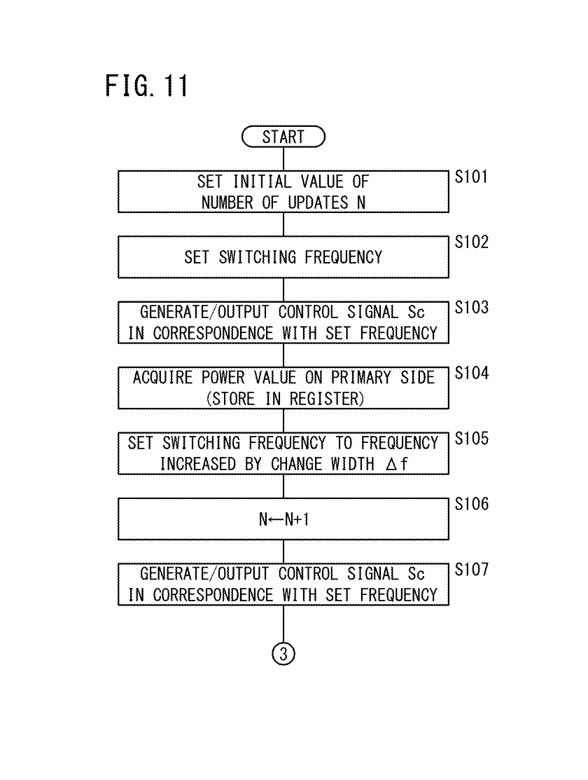

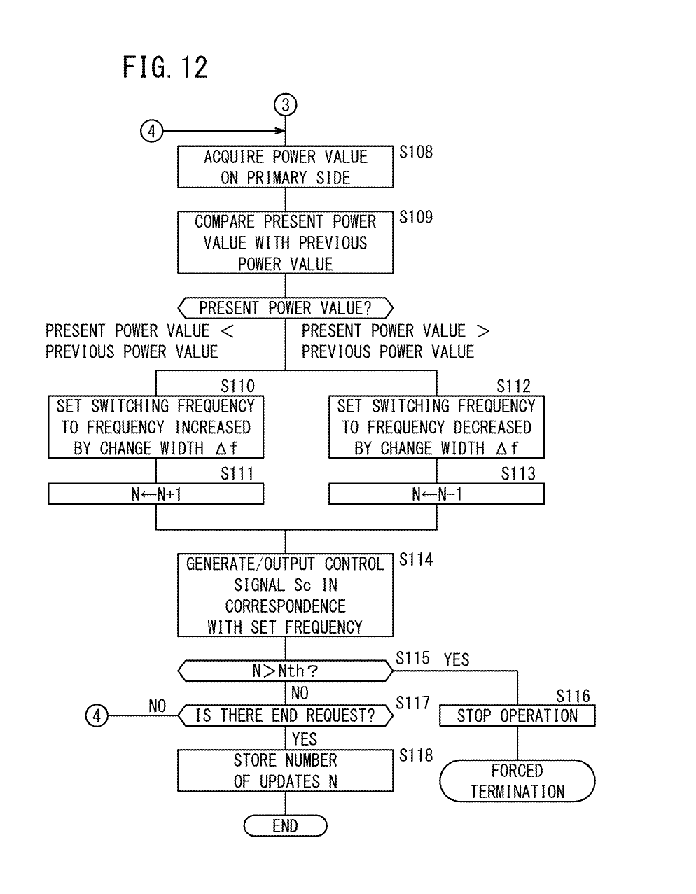

Next, operation of the second ozone generator 10B will be described with reference to FIGS. 11 and 12.

In step S101 of FIG. 11, a failure diagnosis unit 59 reads the number of updates N from a non-volatile memory 60, and stores the read number of updates N as an initial value in a counter 67. At the time of starting operation, since zero is stored in the non-volatile memory 60, zero is stored as an initial value in the counter 67.

In step S102, the second frequency setting unit 64B sets the switching frequency f. Specifically, the number of updates N stored in the non-volatile memory 60 is multiplied by the fixed change width Δf, and the resulting value is added to the reference frequency fb to thereby obtain a frequency. The obtained frequency is set as the switching frequency f. At the time of starting operation, since zero is stored in the non-volatile memory 60, the switching frequency f is set to the reference frequency fb.

In step S103, the second control signal generator unit 66B generates and outputs the control signal Sc in correspondence with the set switching frequency f.

In step S104, the power value acquisition unit 72 determines the power value P1 by multiplying the voltage value V1 from the voltage detection means 70 by the current value I1 from the current detection means 32, and stores the acquired power value P1 in a register 68.

In step S105, the second frequency setting unit 64B sets the switching frequency f to a frequency which is higher than the present frequency by a preset fixed change width Δf.

In step S106, the failure diagnosis unit 59 increments the value (number of updates N) of the counter 67 by 1.

In step S107, the second control signal generator unit 66B generates and outputs the control signal Sc in correspondence with the set frequency.

In step S108 of FIG. 12, the power value acquisition unit 72 multiplies the voltage value V1 from the voltage detection means 70 by the current value I1 from the current detection means 32 to thereby determine the power value P1.

In step S109, the power value comparison unit 74 compares the acquired power value P1 (present power value) with the previous power value P1 stored in the register 68.

If the present power value P1 is lower than the previous power value P1, the routine proceeds to step S110, and the second frequency setting unit 64B sets the switching frequency f to a frequency which is higher than the present frequency by the preset fixed change width Δf.

Thereafter, in step Sill, the failure diagnosis unit 59 increments the value (number of updates N) of the counter 67 by 1.

If the present power value P1 is higher than the previous power value P1, the routine proceeds to step S112, and the second frequency setting unit 64B sets the switching frequency f to a frequency which is lower than the present frequency by the preset fixed change width Δf.

Thereafter, in step S113, the failure diagnosis unit 59 decrements the value (number of updates N) of the counter 67 by 1.

After the process in step S111 or the process in step S113 is finished, the routine proceeds to the next step S114, and the second control signal generator unit 66B generates and outputs the control signal Sc in correspondence with the set switching frequency f.

In next step S115, the failure diagnosis unit 59 determines whether or not the value (number of updates N) of the counter 67 exceeds a threshold value Nth. If the value of the counter 67 exceeds the threshold value Nth, the routine proceeds to step S116, and it is determined that continuation of operation of the second ozone generator 10B is hindered, and operation of the second ozone generator 10B is stopped. Therefore, the process in the second ozone generator 10B is forcibly terminated. An alarm may be issued additionally.

In the above step S115, if it is determined that the value (number of updates N) of the counter 67 is the threshold value Nth or less, in the next steps S117, it is determined whether or not there is a request for the second ozone generator 10B to stop operation. If there is no request to stop operation, the routine returns to step S108 to repeat the processes in step S108 and the subsequent steps.

In step S117, if there is a request to stop operation, the routine proceeds to step S118, and the failure diagnosis unit 59 stores the present number of updates N in the non-volatile memory 60. Thereafter, operation of the second ozone generator 10B is finished.

When operation is resumed, in steps S101 of FIG. 11, the failure diagnosis unit 59 reads the number of updates N from the non-volatile memory 60, and stores the read number of updates N as an initial value in the counter 67. In the subsequent step S102, the number of updates N at the end of the previous operation is multiplied by the fixed change width Δf, and the resulting value is added to the reference frequency fb to thereby obtain a frequency. The obtained frequency is set as the switching frequency f. Then, processes from step S103 and the subsequent steps are repeated.

As described above, also in the second ozone generator 10B, as in the case of the above-described first ozone generator 10A, it is possible to easily and accurately detect open circuit failures of the electrode pairs 40 in the reactor 16, and it is possible simply and reliably determine whether or not operation of the second ozone generator 10B should be continued.

Further, the second ozone generator 10B controls the frequency of the alternating current voltage V2 applied to the reactor 16 such that the power value P1 on the primary side of the transformer 12 is minimized. Thus, it is possible to easily tune the switching frequency f for turning on and off the semiconductor switch 22 to the resonance frequency fc on the secondary side of the transformer 12. Therefore, improvement in the efficiency of the ozone generation can be realized, and the high efficiency can be maintained in ozone generation all the time. Further, since it is not required for the second control circuit 24B to refer to the high voltage, etc. on the secondary side, the circuit structure is simple, and size reduction can be achieved. In the structure, as in the case of the first ozone generator 10A, the second ozone generator 10B can be used suitably, e.g., as an in-vehicle ozone generator.

In particular, since the second ozone generator 10B refers to the power value P1 based on the voltage value V1 and the current value I1 on the primary side, even in the case where the power supply voltage of the direct current power supply unit 14 varies, it is possible to easily tune the switching frequency f for turning on and off the semiconductor switch 22 to the resonance frequency fc on the secondary side of the transformer 12.

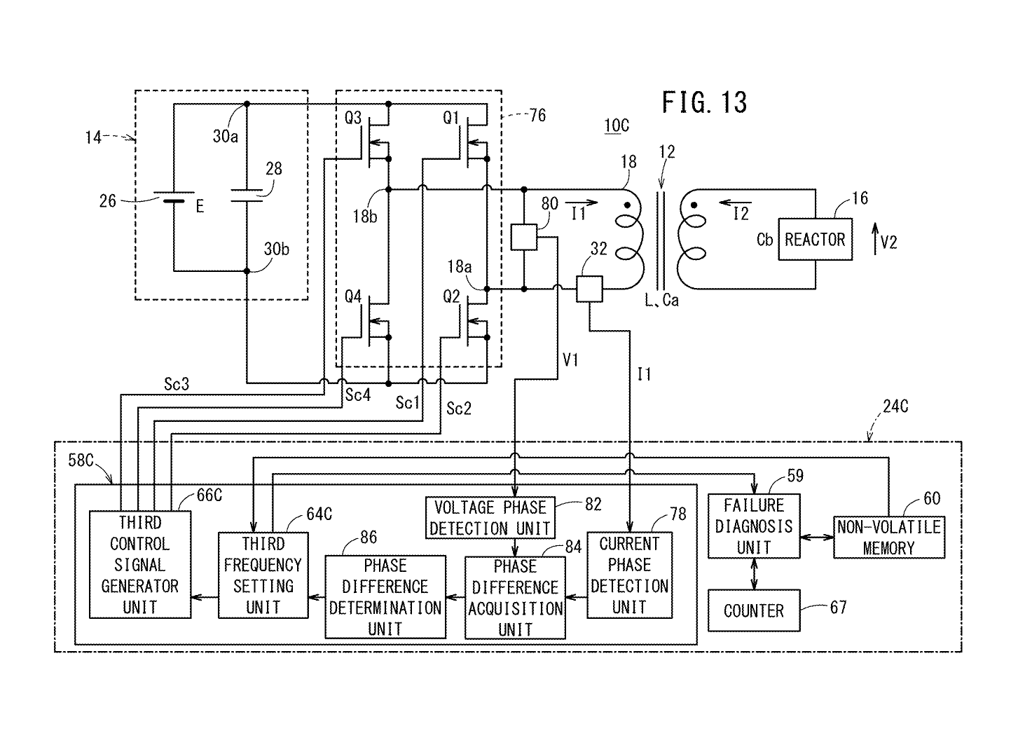

Next, an ozone generator according to a third embodiment of the present invention (hereinafter referred to as a third ozone generator 10C) will be described with reference to FIGS. 13 to 15.

As shown in FIG. 13, the third ozone generator 10C has substantially the same structure as the above described first ozone generator 10A. However, the third ozone generator 10C is different from the first ozone generator 10A in that an inverter 76 is connected between the direct current power supply unit 14 and the transformer 12.

The inverter 76 includes a first semiconductor switch Q1 connected between the positive electrode terminal 30a of the direct current power supply unit 14 and one end 18a of the primary winding 18 of the transformer 12, a second semiconductor switch Q2 connected between the one end 18a of the primary winding 18 and a negative electrode terminal 30b of the direct current power supply unit 14, a third semiconductor switch Q3 connected between a positive electrode terminal 30a of the direct current power supply unit 14 and the other end 18b of the primary winding 18, and a fourth semiconductor switch Q4 connected between the other end 18b of the primary winding 18 and the negative electrode terminal 30b of the direct current power supply unit 14.

A third control circuit 24C of the third ozone generator 10C generates a first control signal Sc1 to a fourth control signal Sc4 for implementing ON-OFF control of the first semiconductor switch Q1 to the fourth semiconductor switch Q4, respectively. For example, in the former half of each cycle, both of, e.g., the second semiconductor switch Q2 and the third semiconductor switch Q3 are turned on, and both of the first semiconductor switch Q1 and the fourth semiconductor switch Q4 are turned off. Consequently, the current (current value I1) on the primary side flows from the other end 18b to the one end 18a of the primary winding 18. In the latter half of each cycle, both of the semiconductor switch Q1 and the fourth semiconductor switch Q4 are turned on, and both of the second semiconductor switch Q2 and the third semiconductor switch Q3 are turned off. Consequently, the current (current value I1) on the primary side flows from the one end 18a to the other end 18b of the primary winding 18. Therefore, alternating current high voltage V2 is applied to the reactor 16.

Further, the third control circuit 24C implements control of the frequency of the alternating current voltage V2 applied to the reactor 16 such that the difference (phase difference θ) between the phase of the voltage (voltage value V1) on the primary side of the transformer 12 and the phase of the current (current value I1) on the primary side of the transformer 12 becomes zero.

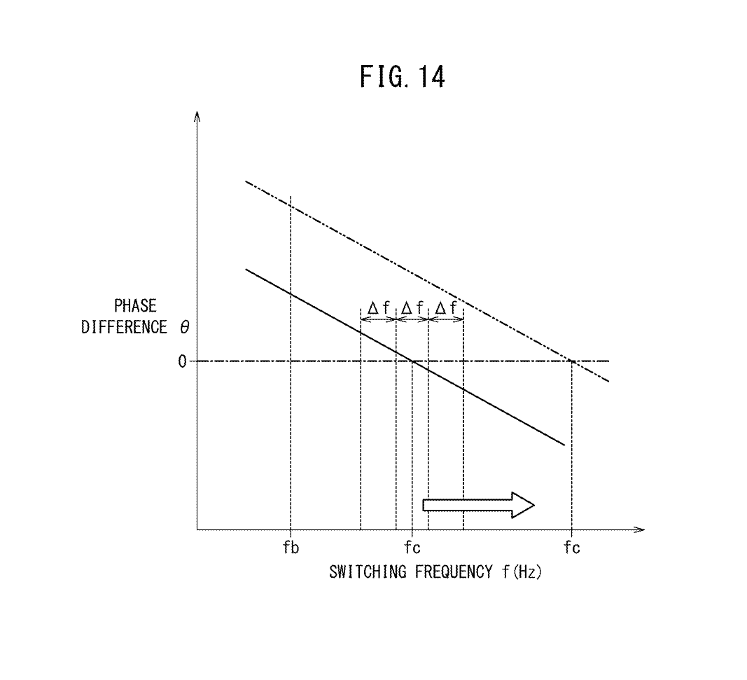

As shown in FIG. 14, when the switching frequency f is successively changed in one direction in increments of the fixed change width Δf, the phase difference θ is decreased gradually. By setting the switching frequency f to a frequency where the phase difference θ becomes zero, it becomes possible to tune the switching frequency f to the resonance frequency fc on the secondary side.

Further, also in this third ozone generator 10C, if the number of failed electrode pairs 40 is increased, e.g., due to aged deterioration of the reactor 16, as shown by a two dot chain line in FIG. 14, the resonance frequency fc on the secondary side is increased. Correspondingly, the number of update times of the switching frequency f (number of updates N) by the fixed change width Δf from the reference frequency fb is increased as well.

In view of the above, as shown in FIG. 13, the third ozone generator 10C includes a third switching control unit 58C, a failure diagnosis unit 59, and a non-volatile memory 60. Further, the third ozone generator 10C includes a current phase detection unit 78 for detecting the phase of the current on the primary side from the current value I1 detected by the current detection means 32, primary voltage detection means 80 for detecting the primary voltage V1 between the one end 18a and the other end 18b of the primary winding 18, and voltage phase detection unit 82 for detecting the phase of the voltage on the primary side from the voltage value V1 detected by the primary voltage detection means 80.

The third switching control unit 58C has a phase difference acquisition unit 84 for calculating the difference (phase difference θ) between the voltage phase from the voltage phase detection unit 82 and the current phase from the current phase detection unit 78, a phase difference determination unit 86 for determining whether the phase difference θ has a positive value or a negative value, a third frequency setting unit 64C for setting the switching frequency f for turning on and off the first semiconductor switch Q1 to the fourth semiconductor switch θ4, in correspondence with transition of the phase difference θ, and a third control signal generator unit 66C for generating, and outputting the first control signal Sc1 to the fourth control signal Sc4 in correspondence with the set switching frequency f.

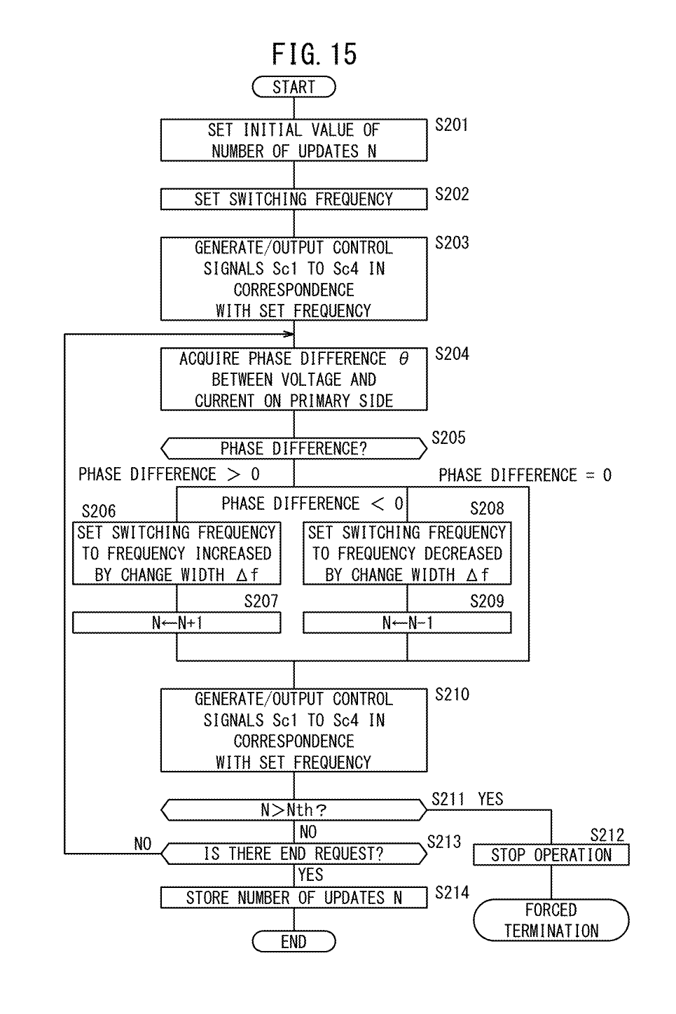

Next, operation of the third ozone generator 10C will be described with reference to FIG. 15.

In step S201 of FIG. 15, the failure diagnosis unit 59 reads the number of updates N from the non-volatile memory 60, and stores the read number of updates N as an initial value in a counter 67. At the time of starting operation, since zero is stored in the non-volatile memory 60, the counter 67 is set to zero as an initial value.

In step S202, the third frequency setting unit 64C sets the switching frequency f. Specifically, the number of updates N stored in the non-volatile memory 60 is multiplied by the fixed change width Δf, and the resulting value is added to the reference frequency fb to thereby obtain a frequency. The obtained frequency is set as the switching frequency f. At the time of starting operation, since zero is stored in the non-volatile memory 60, the switching frequency f is set to the reference frequency fb.

In step S203, the third control signal generator unit 66C generates and outputs the first control signal Sc1 to the fourth control signal Sc4 in correspondence with the set switching frequency f.

In step S204, the phase difference acquisition unit 84 acquires the difference (phase difference θ) between the voltage phase from the voltage phase detection unit 82 and the current phase from the current phase detection unit 78.

In step S205, the phase difference determination unit 86 determines whether the phase difference θ has a positive value or a negative value.

If the phase difference θ has a positive value, the routine proceeds to step S206, and the third frequency setting unit 64C sets the switching frequency f to a frequency which is higher than the present frequency by a preset fixed change width Δf.

Thereafter, in step S207, the failure diagnosis unit 59 increments the value (number of updates N) of the counter 67 by 1.

If the phase difference θ has a negative value, the routine proceeds to step S208, and the third frequency setting unit 64C sets the switching frequency f to a frequency which is lower than the present frequency by the preset fixed change width Δf.

Thereafter, in step S209, the failure diagnosis unit 59 decrements the value (number of updates N) of the counter 67 by 1.

If the phase difference θ is zero, the third frequency setting unit 64C maintains the switching frequency f at the present frequency.

When the process in step S207 or the process in step S209 is finished, or if the phase difference θ is zero, the routine proceeds to the next step S210, and the third control signal generator unit 66C generates and outputs the first control signal Sc1 to the fourth control signal Sc4 in correspondence with the set frequency.

In the next step S211, the failure diagnosis unit 59 determines whether or not the value (number of updates N) of the counter 67 exceeds a threshold value Nth. If the value of the counter 67 exceeds the threshold value Nth, the routine proceeds to step S212, and it is determined that continuation of operation of the third ozone generator 10C is hindered, and thus operation of the third ozone generator 10C is stopped. Therefore, the process in the third ozone generator 10C is forcibly terminated. An alarm may be issued additionally.

In the above step S211, if it is determined that the value (number of updates N) of the counter 67 is the threshold value Nth or less, in the next steps S213, it is determined whether or not there is a request for the third ozone generator 10C to stop operation. If there is no request to stop operation, the routine returns to step S204 to repeat the processes in step S204 and the subsequent steps.

In step S213, if there is a request to stop operation, the routine proceeds to step S214, and the failure diagnosis unit 59 stores the present number of updates N in the non-volatile memory 60. Thereafter, operation of the third ozone generator 10C is finished.

Then, when operation is resumed, in steps S201, the failure diagnosis unit 59 reads the number of updates N from the non-volatile memory 60, and stores the read number of updates N as an initial value in the counter 67. In the subsequent step S202, the number of updates N at the end of the previous operation is multiplied by the fixed change width Δf, and the resulting value is added to the reference frequency fb to thereby obtain a frequency. The obtained frequency is set as the switching frequency f. Then, the processes from step S203 and the subsequent steps are repeated.

As described above, also in the third ozone generator 10C, as in the case of the above described first ozone generator 10A, it is possible to easily and accurately detect open circuit failures of discharge electrodes 42 in the reactor 16, and it is possible simply and reliably determine whether or not operation of the third ozone generator 10C should be continued.

Further, the third ozone generator 10C controls the frequency of the alternating current voltage V2 applied to the reactor 16 such that the phase difference θ between the current on the primary side of the transformer 12 and the voltage on the primary side of the transformer 12 becomes zero. Thus, it is possible to easily tune the switching frequency f for turning on and off the inverter 76 to the resonance frequency fc on the secondary side of the transformer 12. Therefore, improvement in the efficiency of the ozone generation can be easily realized, and the high efficiency in ozone generation can be maintained all the time. Further, since it is not required for the third control circuit 24C to refer to the high voltage, etc. on the secondary side, the circuit structure is simple, and size reduction can be achieved. In the structure, as in the case of the first ozone generator 10A, the third ozone generator 10C can be used suitably. e.g., as an in-vehicle ozone generator.

In particular, since the third ozone generator 10C refers to the phase difference θ between the current and the voltage on the primary side of the transformer 12, the third ozone generator 10C is suitably used as an ozone generator having the inverter 76 connected between the transformer 12 and the direct current power supply unit 14. It is possible to easily tune the switching frequency f for turning on and off the inverter 76 to the resonance frequency fc on the secondary side of the transformer 12.

It is a matter of course that the ozone generator and the method of diagnosing a failure of the ozone generator are not limited to the embodiments described above, and various structures can be adopted without departing from the scope of the invention as defined by the appended claims.

What is claimed is:

1. An ozone generator comprising:
a transformer;
a direct current power supply unit connected to a primary side of the transformer;
a reactor connected to a secondary side of the transformer;
a switching unit connected between at least one end of a primary winding of the transformer and the direct current power supply unit; and
a control circuit configured to implement ON-OFF control of the switching unit using a set switching frequency to thereby apply voltage to the reactor,
wherein the control circuit implements control to minimize electric signal on the primary side of the transformer by updating the switching frequency from a reference frequency by a fixed change width, and determines that a failure has occurred if a number of updates by the fixed change width exceeds a threshold value.

2. The ozone generator according to claim 1, wherein at time of resumption of operation of the ozone generator after end of operation of the ozone generator, the control circuit starts the control from a frequency set at the end of previous operation, instead of the reference frequency; and
the number of updates at the end of the previous operation is used as an initial value, and counting of the number of updates is resumed from the initial value.

3. The ozone generator according to claim 1, wherein the control circuit increments the number of updates each time the switching frequency is updated by the fixed change width in one direction from the reference frequency, and decrements the number of updates each time the switching frequency is updated by the fixed change width in a direction opposite to the one direction.

4. The ozone generator according to claim 1, wherein the reactor includes one or more electrode pairs each comprising two discharge electrodes spaced from each other by a predetermined gap length; and
the reactor generates ozone by allowing a source gas to pass through a space between at least the two discharge electrodes of the electrode pair and then causing electric discharge between the two discharge electrodes by the voltage applied between the two discharge electrodes.

5. The ozone generator according to claim 4, wherein, among the electrode pairs, as the number of electrode pairs having an open circuit failure increases, the number of updates increases.

6. The ozone generator according to claim 5, wherein the threshold value is a number of updates corresponding to a specific number of electrode pairs having an open circuit failure.

7. The ozone generator according to claim 1, wherein the switching unit is connected between the one end of the primary winding of the transformer and the direct current power supply unit.

8. The ozone generator according to claim 7, wherein the control circuit implements control to minimize a current value on the primary side of the transformer by updating the switching frequency from the reference frequency by the fixed change width.

9. The ozone generator according to claim 7, wherein the control circuit implements control to minimize a power value on the primary side of the transformer by updating the switching frequency from the reference frequency by the fixed change width.

10. The ozone generator according to claim 1, wherein the switching unit is connected between both ends of the transformer and both ends of the direct current power supply unit.

11. The ozone generator according to claim 10, wherein the control circuit implements control to cause phase difference between current and voltage on the primary side of the transformer to become zero by updating the switching frequency from the reference frequency by the fixed change width.

12. A method of diagnosing a failure of an ozone generator, the ozone generator including:
a transformer;
a direct current power supply unit connected to a primary side of the transformer;
a reactor connected to a secondary side of the transformer;
a switching unit connected between at least one end of a primary winding of the transformer and the direct current power supply unit; and
a control circuit configured to implement ON-OFF control of the switching unit by a set switching frequency to thereby apply voltage to the reactor,
the method comprising:
a control step of implementing control to minimize electric signal on the primary side of the transformer by updating the switching frequency from a reference frequency by a fixed change width; and
a determination step of determining that a failure has occurred if a number of updates by the fixed change width exceeds a threshold value.

13. The method of diagnosing a failure of the ozone generator according to claim 12, wherein:
at time of resumption of operation of the ozone generator after end of operation of the ozone generator, the control is started from a frequency set at the end of previous operation, instead of the reference frequency; and
the number of updates at the end of the previous operation is used as an initial value, and counting of the number of updates is resumed from the initial value.

14. The method of diagnosing a failure of the ozone generator according to claim 12, wherein
in the control step, the number of updates is incremented each time the switching frequency is updated by the fixed change width in one direction from the reference frequency, and the number of updates is decremented each time the switching frequency is updated by the fixed change width in a direction opposite to the one direction.
